(19) United States
(12) Patent Application Publication
(10) Pub. No.: US 2006/0065901 A1
(43) Pub. Date: Mar. 30, 2006

(54) Migration-proof light-emitting semiconductor device and method of fabrication

(75) Inventors: Hidekazu Aoyagi, Niiza-shi (JP); Takashi Kato, Niiza-shi (JP); Tetsuji Matsuo, Niiza-shi (JP)

Correspondence Address: WOODCOCK WASHBURN LLP, ONE LIBERTY PLACE, 46TH FLOOR, 1650 MARKET STREET, PHILADELPHIA, PA, 19103, US

(73) Assignee: Sanken Electric Co., Ltd.

(21) Appl. No.: 11/233,903

(22) Filed: Sep. 23, 2005

(30) Foreign Application Priority Data
Sep. 29, 2004 (JP) 2004-283566

(51) Int. Cl. H01L 33/00; H01L 31/12

(52) U.S. Cl. 257/79; 257/98

(57) ABSTRACT

An LED has a light-generating semiconductor region formed on an electroconductive baseplate via a reflector layer of silver or silver-base alloy. The light-generating semiconductor region has an active layer between claddings of opposite conductivity types. An anti-migration sheath envelopes either or both of the reflector layer and light-generating semiconductor region in order to prevent the reflector metal from migrating onto the semiconductor region with the consequent possible short-circuiting of the claddings of the active layer.

### CROSS REFERENCE TO RELATED APPLICATIONS

This application claims priority to Japanese Patent Application No. 2004-283566, filed Sep. 29, 2004.

### BACKGROUND OF THE INVENTION

This invention relates to a light-emitting semiconductor device, or light-emitting diode (LED) according to more common parlance, and more particularly to such devices of the class suitable for use in displays and lamps, among other applications. The invention also concerns a method of making such light-emitting semiconductor devices.

The LED has been known which has a light-generating semiconductor region grown in vapor phase on a substrate. Typically, the light-generating semiconductor region has an active layer sandwiched between an n-type cladding or lower confining layer, which overlies the substrate, and a p-type cladding or upper confining layer. Part of the light generated at the active layer directly traverses the upper confining layer and issues from one of the opposite major surfaces of the semiconductor region. The rest of the light is radiated more or less toward the substrate via the lower confining layer. How to redirect the highest percentage of this light component back toward the light-emitting surface of the semiconductor region is of critical importance for the maximum possible efficiency of the LED.

One conventional approach to this goal was to place a reflector layer on the underside of the substrate, for reflecting the light that has traveled through the substrate. An obvious drawback to this approach was the inevitable light absorption by the substrate, both before and after reflection by the reflector. Lying in the way of bidirectional light travel, the substrate significantly lessened the efficiency of the LED.

Another known solution was an electroconductive substrate, on one of the pair of opposite major surfaces of which was formed the light-generating semiconductor region. The other major surface of the substrate was covered with a cathode. This solution is objectionable for a relatively high forward voltage required for driving the LED, and consequent power loss, as a result of high electric resistance at the interface between the light-generating semiconductor region and the electroconductive baseplate.

Japanese Unexamined Patent Publication No. 2002-217450, filed by the assignee of the instant application, represents an improvement over the more conventional devices listed above. It teaches the creation of an open-worked layer of gold-germanium-gallium alloy on the underside of the light-generating semiconductor region. This open-worked alloy layer, as well as the surface parts of the semiconductor region left uncovered thereby, is covered by a reflector layer of aluminum or other metal. An electroconductive silicon baseplate is bonded to the underside of the reflective layer. Making good ohmic contact with the light-generating semiconductor region of Groups III-V compound semiconductors such as, say, aluminum gallium indium phosphide, the open-worked gold-germanium-gallium alloy regions serves for reduction of the forward voltage of the LED.

The reflector layer itself of this prior art LED reflects the light reflects the light impinging thereon via the open-worked alloy layer, instead of via the substrate as in the more conventional device. A significant improvement was thus gained in efficiency.

The last cited prior art LED proved to possess its own weaknesses, however. Although capable of low-resistance contact with the light-generating semiconductor region, the open-worked layer of gold-germanium-gallium alloy lacks in reflectivity. The metal-made reflector layer on the other hand is reflective enough but incapable of low-resistance contact with the light-generating semiconductor region. These facts combined to make it difficult for the LED to attain the dual objective of low forward voltage and high efficiency light emission.

It might be contemplated to substitute a layer of silver or silver-base alloy for the open-worked gold-germanium-gallium layer and aluminum reflector. Silver or silver-base alloy is superior to aluminum in both reflectivity and capability of ohmic contact with the light-generating semiconductor region. However, silver, silver-base alloy and aluminum are alike in susceptibility to migration with the lapse of time and/or changes in temperature. The migrating metal may provide a short-circuit path between the n- and p-type claddings of the light-generating semiconductor region by adhering to the side of the LED. On being so shorted while being driven with a constant current, the LED will suffer a drop in its anode-cathode voltage and, in consequence, in output light intensity. It may also be pointed out that the LED specialists have so far paid little or no attention to the side of the light-generating semiconductor region either for prevention of metal migration or for utmost light emission.

### SUMMARY OF THE INVENTION

The present invention has it as an object to preclude, in a light-generating semiconductor device of the kind defined, the short-circuiting of the light-generating semiconductor region by metal migration from the reflector or equivalent part of the device.

Briefly, the invention concerns a migration-proof light-emitting semiconductor device comprising a light-generating semiconductor region coupled to a baseplate via a conductor layer such as a metal-made reflector. The conductor layer is made from a metal that is relatively easy to migrate with the lapse of time or change in temperature. In order to prevent the metal of the conductor layer from migrating onto the light-generating semiconductor region, an anti-migration sheath envelopes at least either of the conductor layer and the light-generating semiconductor region. The anti-migration sheath itself has to be higher in electric resistivity than the conductor layer and the light-generating semiconductor region for the proper functioning of the device.

The conductor layer takes the form of a reflector of silver or silver-base alloy, or aluminum or aluminum-base alloy, in the various embodiments of the invention disclosed herein. The light-generating semiconductor region comprises an active layer sandwiched between a pair of claddings or confining layers of opposite conductivity types. The anti-migration sheath covers both the reflector layer and the light-generating semiconductor region, as well as part of the baseplate, in some embodiments of the invention, but does so only either of the reflector layer and light-generating semiconductor region in others.

When covering only the light-generating semiconductor region, the anti-migration sheath keeps the claddings of the opposite conductivity types from short-circuiting the active layer due to the metal migrating from the reflector layer. Migration itself from the reflector layer is prevented when the anti-migration sheath envelopes only the reflector layer. Short-circuiting due to reflector metal migration is even more positively inhibited when both the light-generating semiconductor region and the reflector layer are sheathed.

The invention also concerns a method of fabricating the migration-proof light-emitting semiconductor device of the above summarized construction. The constituent layers of the main semiconductor region thereon are successively grown in a vapor phase on a substrate. The thus-formed light-generating semiconductor region having a first major surface facing away from the substrate and a second major surface held against the substrate. Then a baseplate is bonded to the first major surface of the light-generating semiconductor region. The bonding metal used at this time, such as silver or silver-base alloy, creates the reflector or other conductor layer between the light-generating semiconductor region and the baseplate. The substrate, which becomes unnecessary upon completion of the light-generating semiconductor region thereon, is removed either before or after the bonding of the baseplate. Then, perhaps after creating an electrode or electrodes, the anti-migration sheath is formed around at least either of the conductor layer and the light-generating semiconductor region.

Preferably, for bonding the baseplate to the light-generating semiconductor region, bonding metal layers are preformed on both baseplate and light-generating semiconductor region. Then the preformed bonding metal layers are joined under heat and pressure into the reflector or other conductor layer. The anti-migration sheath can be formed by any such method as sputter, vapor deposition, coating, or ion implantation.

The above and other objects, features and advantages of this invention will become more apparent, and the invention itself will best be understood, from a study of the following description and appended claims, with reference had to the attached drawings showing some preferable embodiments of the invention.

### BRIEF DESCRIPTION OF THE DRAWINGS

FIG. 1 is a sectional illustration of a migration-proof LED embodying the principles of this invention.

FIG. 2 is a section through the light-generating semiconductor region of the LED, shown together with the substrate on which it has been grown, by way of a first step for fabricating the LED of FIG. 1 by the method of this invention.

FIG. 3 is a view similar to FIG. 2 except for a bonding agent layer formed on the light-generating semiconductor region.

FIG. 4 is also a view similar to FIG. 2 but showing a baseplate together with a second bonding agent layer formed thereon.

FIG. 5 is also a view similar to FIG. 2 but showing the light-generating semiconductor region of FIG. 3 and the baseplate of FIG. 4 bonded together via the two preformed bonding agent layers.

FIG. 6 is a view similar to FIG. 5 but not showing the substrate, the latter having been removed from the light-generating semiconductor region.

FIG. 7 is a graph explanatory of what would take place should the light-generating semiconductor region be short circuited by the migrating metal.

FIG. 8 is a sectional illustration of another preferred form of migration-proof LED according to the invention.

FIG. 9 is a sectional illustration of still another preferred form of migration-proof LED according to the invention.

FIG. 10 is a sectional illustration of yet another preferred form of migration-proof LED according to the invention.

FIG. 11 is a sectional illustration of a further preferred form of migration-proof LED according to the invention.

FIG. 12 is a sectional illustration of a further preferred form of migration-proof LED according to the invention.

FIG. 13 is a sectional illustration of a further preferred form of migration-proof LED according to the invention.

FIG. 14 is a sectional illustration of a still further preferred form of migration-proof LED according to the invention.

### DETAILED DESCRIPTION OF THE INVENTION

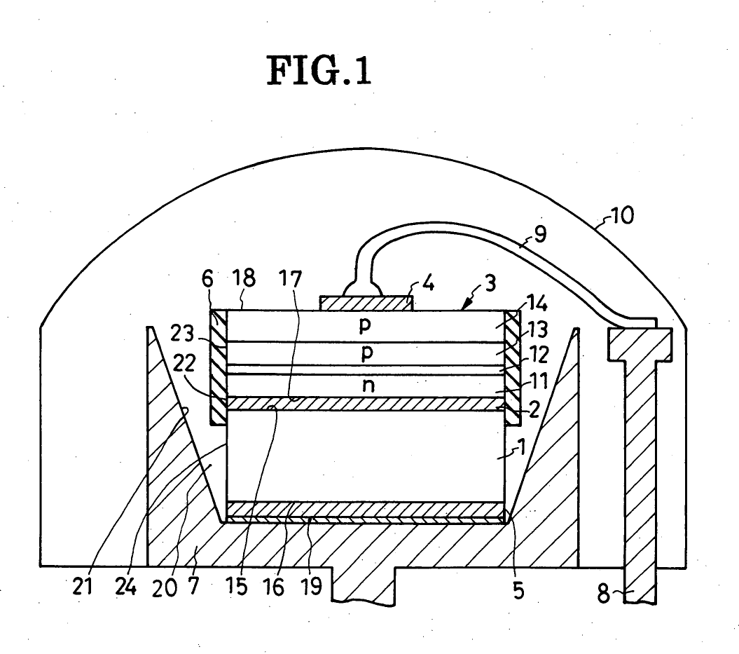

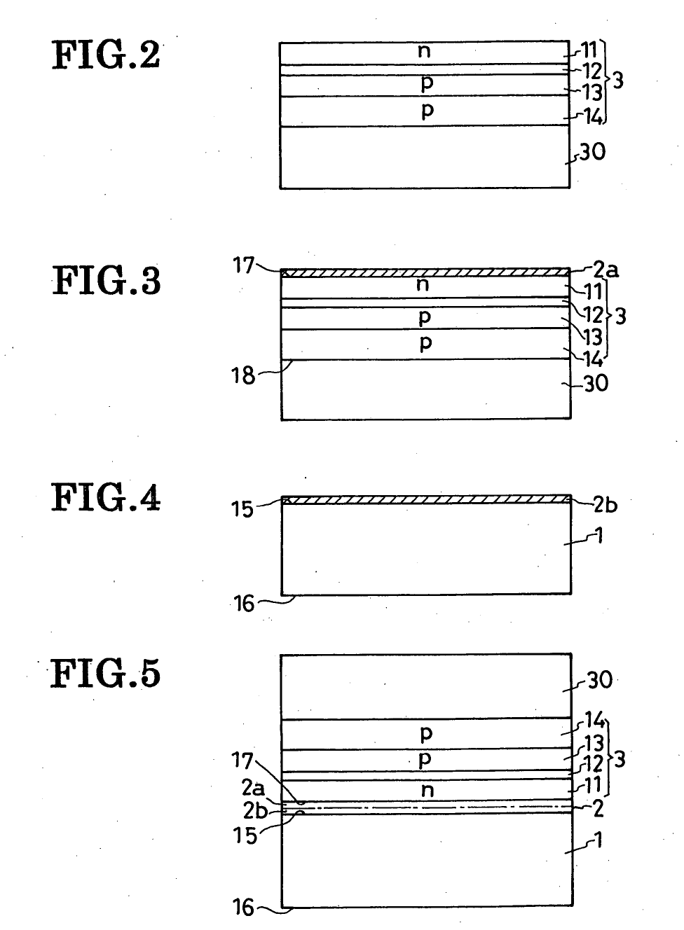

The present invention is believed to be best embodied in the LED shown completed in FIG. 1 and in successive states of fabrication in FIGS. 2-6. The representative LED of FIG. 1 broadly comprises:

1. An electroconductive baseplate 1 providing both mechanical support and current path for the LED.

2. A reflector layer 2 of electroconductive material directly overlying the baseplate 1.

3. A light-generating semiconductor region 3 where light is produced and which is herein shown constituted of four layers in lamination to be detailed shortly.

4. A first electrode or anode 4 in the form of a bonding pad positioned centrally on one of the pair of opposite major surfaces of the light-generating semiconductor region 3.

5. A second electrode or cathode 5 formed on the complete underside of the baseplate 1.

6. An anti-migration sheath 6, a feature of the instant invention, which is herein shown covering parts or all of the exposed sides of the baseplate 1, reflector layer 2 and light-generating semiconductor region 3.

7. A metal-made, cuplike seat 7 to which is mounted the LED chip comprising all the parts or components listed in the foregoing and which has a reflective inside surface for redirecting the light coming from the side of the LED chip outwardly of the device.

8. A lead 8 wired at 9 to the bonding-pad anode 4.

9. A plastic encapsulation 10 integrally enveloping the complete LED chip and parts of the LED seat 7 and lead 8.

In order to provide a double heterojunction LED as one possible application of the invention, the light-generating semiconductor region 3 comprises an n-type semiconductor layer or lower cladding 11, an active layer 12, a p-type semiconductor layer or upper cladding 13, and a p-type complementary semiconductor layer 14, all grown in vapor phase in a reversal of that order on a substrate, seen at 30 in FIGS. 2 and 3, of gallium arsenide or the like. The substrate 30 is unseen in FIG. 1 because it is removed following the growth of all the constituent layers 11-14 of the light-generating semiconductor region 3 thereon and is absent from the completed LED. The compositions of the constituent layers 11-14 of the light-generating semiconductor region 3 will be detailed later.

The baseplate 1 is made from an electroconductive silicon semiconductor to include a pair of opposite major surfaces 15 and 16. The reflector layer 2 is formed on the first major surface 15, and the cathode 5 on the second major surface 16. The baseplate 1 is doped with an n-type impurity to a concentration of 5×10¹⁸ through 5×10¹⁹ cm⁻³, but a p-type dopant may be employed instead. In order to provide a current path between the electrodes 4 and 5, the baseplate 1 is as low in resistivity as from 0.0001 to 0.0100 ohm-cm. The baseplate 1 is sufficiently thick (e.g., from 300 to 1000 micrometers) to serve as a mechanical support for the reflector layer 2, light-generating semiconductor region 3, and electrodes 4 and 5.

Interposed between baseplate 1 and light-generating semiconductor region 3, the reflector layer 2 makes ohmic contact with both the major surface 15 of the former and the major surface 17 of the latter. It is desired that the reflector layer 2 reflect not less than ninety percent of the light in the wavelength range of 400 to 600 nanometers coming from the light-generating semiconductor region 3. Besides being so reflective, the reflector layer 2 should be higher in electric conductivity than the light-generating semiconductor region 3. Materials that meet these requirements include silver and silver-base alloy. Currently believed to be most desirable is a silver-base alloy containing from 90.0 to 99.5 percent by weight silver, and from 0.5 to 10.0 percent by weight additive or additives. The additive or additives may be chosen from among such alloyable metals as copper, gold, palladium, neodymium, silicon, iridium, nickel, tungsten, zinc, gallium, titanium, magnesium, yttrium, indium, and tin.

The additives listed above are effective for one or more of the purposes of: (a) preventing the oxidation of the reflector layer 2; (b) preventing the sulfurization of the reflector layer 2; and (c) preventing the alloying of the metals in the reflector layer 2 and light-generating semiconductor region 3. Copper and gold are especially good for anti-oxidation, and zinc and tin for anti-sulfurization. Should the silver or silver-base alloy reflector layer 2 be oxidized or sulfurized, this layer would make poorer ohmic contact with the baseplate 1 and light-generating semiconductor region 3 and also suffer in reflectivity. The reflector layer 2 would also become less reflective in the event of the appearance of a thick alloy layer at its interface with the light-generating semiconductor region 3. Furthermore, as will become more apparent from the subsequent presentation of the method of fabrication, the reflector layer 2 is used for bonding the light-generating semiconductor region 3 to the baseplate 1 as well. The reflector layer 2 on oxidation or sulfurization would seriously hamper such bonding.

In use of a silver-base alloy for the reflector layer 2, the higher the proportion of the additive or additives, the less will the resulting layer be susceptible to oxidation or sulfurization, but, at the same time, the less reflective will it be. Therefore, in order to assure higher reflectivity and ohmic contact for the reflector layer 2 than those of the reflector in Unexamined Japanese Patent Publication No. 2002-217450, supra, required proportion of the additive or additives with respect to that of silver is hereby set in the range of 0.5 through 10.0 percent by weight, preferably from 0.5 to 5.0 percent by weight. The reflector layer would not be sufficiently immune from oxidation or sulfurization if the additive proportion were less than 0.5 percent by weight, and not sufficiently reflective if the additive proportion is over 10.0 percent by weight.

The reflector layer 2 should be not less than 50 nanometers in order to prevent transmission of the light therethrough, and not less than 80 nanometers for firmly bonding the light-generating semiconductor region 3 to the baseplate 1. However, the silver or silver-base alloy reflector layer 2 would crack if the thickness exceeded 1500 nanometers. The reflector layer 2 should therefore be from 50 to 1500 nanometers thick, preferably from 80 to 1000 nanometers thick.

The light-generating semiconductor region 3 comprises as aforesaid the n-type lower cladding 11, active layer 12, p-type upper cladding 13, and p-type complementary semiconductor layer 14, preferably all of nitride semiconductors or other Groups III-V compound semiconductors. The light-generating semiconductor region 3 need not necessarily be of double heterojunction configuration; instead, the active layer 12 may be omitted, and the two claddings or semiconductor layers of opposite conductivity types directly held against each other. It is also possible to omit the p-type complementary semiconductor layer 14. The light-generating semiconductor region 3 as a whole has a pair of opposite major surfaces 17 and 18. The light issues from the major surface 18.

Aside from impurities, the n-type cladding 11 is fabricated from any of nitride semiconductors that are generally defined as:
AlₓIn_{y}Ga_{1-x-y}N
where the subscripts x and y are both numerals that are equal to or greater than zero and less than one. Thus the formula encompasses not only aluminum indium gallium nitride but also indium gallium nitride (x=0), aluminum gallium nitride (y=0), and gallium nitride (x=0, y=0).

Overlying the n-type cladding 11, the active layer 12 is made from any of undoped nitride semiconductors that are generally expressed as:
AlₓIn_{y}Ga_{1-x-y}N
where the subscripts x and y are both numerals that are equal to or greater than zero and less than one. Currently preferred is InGaN (x=0). In practice the active layer 12 may take the form of either multiple or single quantum well structure. The active layer 12 may also be doped with a p- or n-type conductivity determinant.

The p-type cladding 13 over the active layer 12 is made by adding a p-type impurity to any of the nitride semiconductors that are generally defined as:
AlₓIn_{y}Ga_{1-x-y}N
where the subscripts x and y are both numerals that are equal to or greater than zero and less than one. Currently preferred is p-type GaN (x=0, y=0).

The p-type complementary layer 14 over the p-type cladding 13 serves both for uniformity of current distribution and for making better ohmic contact with the anode 4. It is made from GaN, the same material as the cladding 13, but with a p-type impurity added to a higher concentration than that of that cladding.

As required or desired, this complementary layer 14 may take the form of a required number of alternations of a first and a second complementary sublayer. The first complementary sublayers are of a p-type nitride semiconductor with a prescribed proportion of aluminum. The second complementary sublayers are of a p-type nitride semiconductor that either does not contain aluminum or that does contain aluminum in a less proportion than that of the first complementary sublayers. Each first complementary sublayer may be from 0.5 to 10.0 nanometers thick, and each second complementary sublayers from 1 to 100 nanometers thick.

More specifically, aside from impurities, the first complementary sublayers may be made from any of the nitrides that are generally defined as:
AlₓM_{y}Ga_{1-x-y}N
where M is at least either of indium and boron; the subscript x is a numeral that is greater than zero and equal to or less than one; the subscript y is a numeral that is equal to or greater than zero and less than one; and the sum of x and y is equal to or less than one.

Also, aside from impurities, the second complementary sublayers may be made from any of the nitrides that are generally defined as:
AlₐM_{b}Ga_{1-x-b}N
where M is at least either of indium and boron; the subscripts a and b are both numerals that are equal to or greater than zero and less than one; the sum of a and b is equal to or less than one; and the subscript a is less than the subscript x in the formula above defining the materials for the first complementary sublayers.

The anode 4 is placed centrally on the surface of the complementary layer 14, or on the major surface 18 of the light-generating semiconductor region 3, and electrically coupled thereto. The anode 4 is shown as a bonding pad, preferably opaque, which permits the bonding of the wire 9 for connection to the lead 8. The cathode 5 underlies the complete major surface 16 of the baseplate 1 and makes ohmic contact therewith.

FIG. 1 also shows the metal-made seat 7 of cuplike shape to which the LED chip of the foregoing construction is mounted. Received with clearance in an open-top hollow 20 in the seat 7, the LED chip is affixed to the bottom of the seat by having its cathode 5 joined thereto via a layer 19 of an electroconductive bonding agent. The sidewall bounding the hollow 20 has a reflective inside surface 21 capable of reflecting the light from the LED chip approximately in the same direction as the light issuing from the major surface 18 of the light-generating semiconductor region 3. The reflective sidewall surface 21 is shown in FIG. 1 to be steeper than its actual angle with respect to the bottom of the hollow 20, and hence to the major surface 18 of the light-generating semiconductor region 3, in order to save space.

Molded from a transparent synthetic resin, the encapsulation 10 envelops all of the LED chip, the electrodes 4 and 5, and the wire 9 as well as parts of the seat 7 and lead 9. The encapsulation 10 is electrically insulating and so holds the lead 8 electrically disconnected from the metal-made seat 7.

The anti-migration sheath 6 is shown in FIG. 1 as covering the side 22 of the reflector layer 2, the side 23 of the light-generating semiconductor region 3, and part of the side 24 of the baseplate 1. Alternatively, however, the anti-migration sheath 6 may cover either of:

1. The side 22 of the reflector layer 2.

2. The sides of the active layer 12, p-type cladding 13 and p-type complementary semiconductor layer 14 of the light-generating semiconductor region 3, but not the side of the n-type cladding 11 which makes direct electric contact with the reflector layer 2.

3. Both of the foregoing two.

4. The side 22 of the reflector layer 2 and side 23 of the light-generating semiconductor region 3.

5. Either of the above and all or part of the major surface 18 of the semiconductor region 3.

6. Either of the above and all of the side 24 of the baseplate 1.

The anti-migration sheath 6 is made from an insulator or semiconductor that makes closer contact with the reflector layer 2 and light-generating semiconductor region 3, that is higher in resistivity than the light-generating semiconductor region, and that is, moreover, transparent. Also, the anti-migration sheath 6 is better than the transparent encapsulation 10 in adhesion nature with the reflector layer 2 and light-generating semiconductor region 3. The transparency of the anti-migration sheath 6 is particularly desirable in cases where the light-generating semiconductor region 3 is of constant diameter throughout its dimension between the pair of opposite major surfaces 17 and 18 as in the embodiment of FIG. 1 or, as in that of FIG. 10 yet to be described, tapers from one major surface 17 toward the other 18 of the light-generating semiconductor region. The anti-migration sheath 6 will possess all the required properties if made from such inorganic compounds as silicon oxide (SiO₂), silicon nitride (SiN₄), and titanium oxide (TiO₂).

The thickness and refractivity of the anti-migration sheath 6 may be so determined as to restrict the total reflection of light at its interfaces with the light-generating semiconductor region 3 and with the transparent encapsulation 10. A reduction of total reflection at these interfaces will lead to improvement in the efficiency with which the light is emitted via the anti-migration sheath 6 and encapsulation 10.

To be more specific, the refractivity and thickness of the anti-migration sheath 6 may be determined according to the following equations for reduction of total reflection at the interfaces of the anti-migration sheath with the light-generating semiconductor region 3 and with the transparent encapsulation 10:
(n₁×n₃)^{1/2}×0.8≦n₂≦(n₁×n₃)^{1/2}×1.2
T=[(2m+1)×λ/4n₂](λ/8n₂)
where
n₁=refractivity of the light-generating semiconductor region 3
n₂ refractivity of the anti-migration sheath 6
n₃=refractivity of the transparent encapsulation 10
T=thickness of the anti-migration sheath 6
m=either 0, 1 or 2
λ=wavelength of the light generated.

In the absence of the encapsulation 10, not an essential feature of the invention, the thickness and refractivity of the anti-migration sheath 6 may be determined according to the following equations for reduction of total reflection at its interface with the light-generating semiconductor region 3:
(n₁×n₄)^{1/2}×0.8≦n₂≦(n₁×n₄)^{1/2}×1.2
T=[(2m+1)×λ/4n₂]±(λ/8n₂)
where n₄ is the refractivity of the air.

The thickness of the anti-migration sheath 6 may not necessarily be determined according to the equation above. The total reflection will be reduced appreciably only if the anti-migration sheath 6 has its refractivity set in the above defined range. A reduction of the total reflection will lead to a higher efficiency of light emission and a greater intensity of the light emitted. The anti-migration sheath 6 may be formed by any such known method as sputtering, vapor deposition, or coating, before the LED chip is bonded to the seat 7.

### Method of Fabrication

The fabrication of the migration-proof LED of FIG. 1 by the method of this invention starts with the preparation of the substrate seen at 30 in FIG. 2. Unlike the baseplate 1 seen in FIG. 1, the substrate 30 is intended for gaseous-phase growth of the light-generating semiconductor region 3 thereon, so that it must be of a substance that meets this objective. Examples of such a substance include gallium arsenide or like Groups III-V semiconductors, silicon, and sapphire. Silicon in particular is desirable for its low cost.

Then, as pictured also in FIG. 2, the light-generating semiconductor region 3 is grown in gaseous phase on the substrate 30 in the order of top to bottom in FIG. 1, that is, the complementary layer 14 first and the cladding 11 last. First grown on the substrate 30, the complementary layer 41 serves as a buffer for the cladding 13, active layer 12 and cladding 11 grown subsequently.

The next step is the bonding of the baseplate 1 to the light-generating semiconductor region 3 grown as above on the substrate 30. It is recommended that the baseplate 1 be bonded to the light-generating semiconductor region 3 via layers of a bonding agent, such as silver or silver-base alloy, that lend themselves to use as the reflector layer 2 on being joined to each other under heat and pressure. Toward this end a bonding agent layer 2ₐ, FIG. 3, may be formed as by sputtering on the major surface 17 of the light-generating semiconductor region 3, to a thickness approximately equal to half the thickness of the reflector layer 2 to be formed.

Another bonding agent layer 2_{b}, FIG. 4, may be formed on the surface 15 of the electroconductive silicon baseplate 1, also as by sputtering of silver or silver-base alloy. This second bonding agent layer may also be made to a thickness approximately equal to half the thickness of the desired reflector layer 2.

FIG. 5 shows the first bonding agent layer 2ₐ on the surface 17 of the light-generating semiconductor region 3 subsequently held against the second bonding agent layer 2_{b} on the surface 15 of the baseplate 1. Heated to a temperature in the range of 210° to 400° C. under pressure, the two bonding agent layer 2ₐ and 2_{b} unite into the reflector layer 2. If made from silver, in particular, the bonding agent layers 2ₐ and 2_{b} have their surfaces freed from oxidation or sulfurization films etching preparatory to being joined as above under heat and pressure. Whether of silver or silver-base alloy, the reflector layer 2 will make hood ohmic contact with both baseplate 1 and light-generating semiconductor region 3 and be higher in reflectivity than that of aluminum.

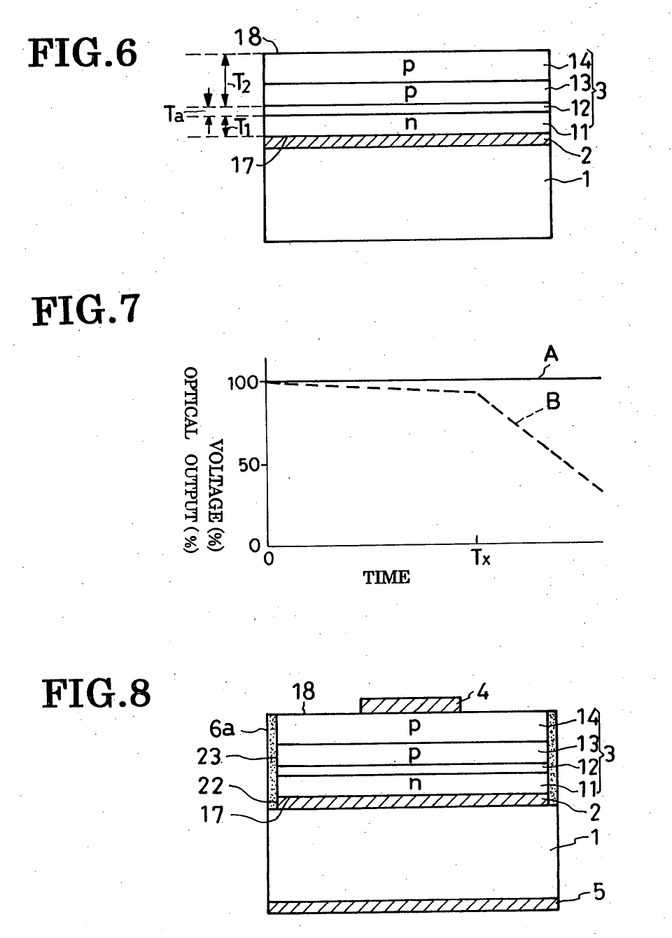

Then the substrate 30 is removed from the light-generating semiconductor region 3 as in FIG. 6, thereby exposing the second major surface 18 of that region. The substrate 30 is removable either chemically, as by etching, or mechanically. Having been unnecessary upon completion of the light-generating semiconductor region 3 thereon, the substrate 30 may be removed prior to the bonding of the baseplate 1 to the light-generating semiconductor region 1.

Then the anti-migration sheath 6 is formed on any required part or whole of the side of the LED chip formed as above. Then the electrodes 4 and 5 are conventionally formed on the LED chip, in the positions indicated in FIG. 1.

In the operation of the FIG. 1 LED, constructed and manufactured as in the foregoing, light will be generated at the active layer 12 of the semiconductor region 3 upon application of a forward voltage between the electrodes 4 and 5. Radiated toward the second major surface 18 of the semiconductor region 3, part of the light will be emitted through that part of the surface 18 which is left exposed by the electrode 4. The rest of the light will fall either on the reflector 2 or on the side 23 of the LED chip. Impinging upon the reflector 2, the light will be thereby reflected toward the second major surface 18 and issue therethrough together with the light that has been directly radiated toward the same. The light that has irradiated the side 23 of the LED chip will mostly pass the anti-migration sheath 6 and, reflected by the slanting inside surface 21 of the seat 7, be redirected to emerge from the LED together with the light issuing from the major surface 18 of the semiconductor region 3.

Having thus described the first preferred embodiment of the invention, let us now reexamine the advantages offered by the anti-migration sheath 6. Were it not for this anti-migration sheath, the metal from which the reflector 2 was made might migrate and adhere to the side 23 of the LED chip either during the LED fabrication or in the course of subsequent handling or use. Such adhesion of the migrant metal was particularly liable to occur in cases where the reflector layer protruded laterally beyond the light-generating semiconductor region. The lateral protrusion of the reflector layer is almost unavoidable when the side of the LED chip is conventionally wet etched, because the reflector layer is proof against etching. Metal migration from the protruding part of the reflector layer was particularly easy to occur by reason of electric field concentration at that part upon application of a driving voltage the LED. The possible result, in the absence of the anti-migration sheath 6, was the short-circuiting of the claddings 11 and 13 on opposite sides of the active layer 12 by the migrant metal on the side 23 of the LED chip.

As indicated by the solid line A in FIG. 7, both the voltage across the LED and the optical output therefrom will be constant as long as the LED is being driven with a constant current, without the short-circuiting of the claddings of the active layer. If the claddings are short-circuited, however, both the voltage and output start declining upon lapse of a certain length of time Tₓ following the start of LED energization, like the broken line B in the same graph.

No such trouble will occur thanks to the anti-migration sheath 6 according to the invention. Even if the reflector layer 2 bulges out after the wet etching of the LED chip, the anti-migration sheath 6 of electrically insulating material wholly covers such bulging part of the reflector layer, mitigating field concentration at that part and so preventing the migration of the reflector metal. The reflector metal would migrate in the absence of the anti-migration sheath 6 even if the reflector layer did not protrude laterally of the LED chip. The anti-migration sheath according to the invention will prevent the migration in that case too.

Possibly, in the course of the manufacturing process or thereafter, the reflector layer 2 may expand and penetrate the anti-migration sheath 6. The reflector metal may then migrate onto the surface of the anti-migration sheath 6 from the projecting tip of the reflector layer 2. However, if formed in a width greater than that Tₐ, FIG. 6, of the exposed side surface of the active layer 12, the anti-migration sheath 6 will effectively prevent the migrant reflector metal from short-circuiting the claddings 11 and 13.

As was set forth with reference to FIGS. 2-6, the manufacturing method of this invention dictates the growth of the light-generating semiconductor region 3 on the substrate 30, and the bonding of the baseplate 1 to the first major surface 17 of the semiconductor region 3 which has not been held against the substrate. This method makes the thickness T₁, FIG. 6, of the n-type cladding 11 less than the total thickness T₂ of the p-type cladding 13 and p-type complementary layer 14, resulting in reduction of the distance between the active layer 12 and the reflector layer 2 through which the baseplate is bonded to the light-generating semiconductor region 3. Were it not for the anti-migration sheath 6, the reflector metal would be easier to migrate onto the exposed side of the active layer 12. The anti-migration sheath 6 prevents the reflector metal migration onto the side of the active layer 12 despite the reduced distance from the reflector to the active layer, protecting the light-generating semiconductor region 3 against short-circuiting.

The following is a list of additional advantages obtained by this first preferred embodiment of the invention:

1. The anti-migration sheath 6 both insulates and makes moisture proof the side 23 of the LED chip moisture-proof, protecting the LED against overvoltage breakdown due for example to static electricity.

2. The reflector layer 2 is formed simply as the baseplate 1 is affixed to the light-generating semiconductor region 3 via the bonding agent layers 2ₐ and 2_{b}.

3. Made from silver or silver-base alloy, the reflector layer makes good ohmic contact with both silicon baseplate 1 and light-generating semiconductor region 3. Therefore, unlike the prior art cited earlier in this specification, the reflector layer needs no additional layers for ohmic contact with the neighboring parts. Not only is the LED made simpler in construction, but also the device is higher in the percentage of the light that is reflected without being wasted. Further the LED requires a less forward voltage for providing an optical output of given intensity and so incurs less power loss.

4. The anti-migration sheath 6 is intermediate in refractivity between the light generating semiconductor region 3 an the plastic encapsulation 10 or air and transparent to the light from the active layer 12. The light that has passed the anti-migration sheath 6 is redirected by the inside surface 21 of the cup-shaped seat 7 to emit from the LED together with the light issuing from the major surface 18 of the light-generating semiconductor region 3.

### Embodiment of FIG. 8

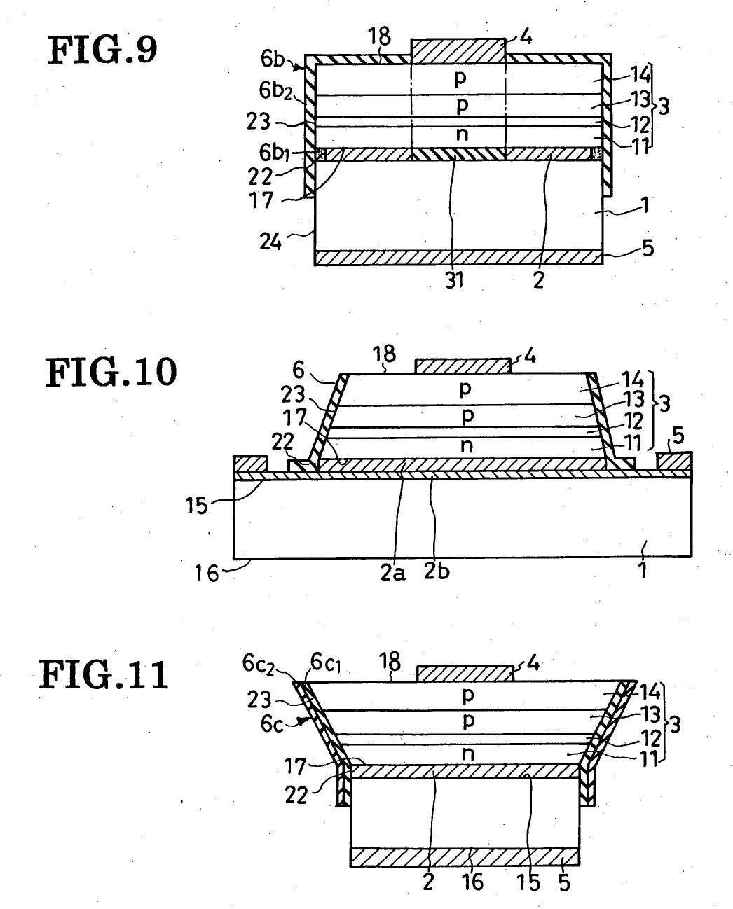

FIG. 8 shows another preferred form of LED chip embodying the principles of this invention. This LED chip, as well as all the additional forms to be described subsequently with reference to FIGS. 9-14, is understood to be furnished with a seat, lead, wire, and encapsulation similar to those seen respectively at 7, 8, 9 and 10 in FIG. 1. These parts do not appear in FIGS. 8-14 for simplicity.

The LED chip of FIG. 8 features a modified anti-migration sheath 6ₐ of electrically insulating material on the side 22 of the reflector layer 2 and the side 23 of the light-generating semiconductor region 3. The insulating anti-migration sheath 6ₐ can be formed by ion implantation into the reflector layer 2 and semiconductor region 3. Thus the sheath 6ₐ on the reflector layer 2 may be of a metal oxide formed by ion implantation into the silver or the like constituting the reflector layer. The sheath 6ₐ on the light-generating semiconductor region 3 may be formed by hydrogen or oxygen ion implantation.

Created by ion implantation as above, the anti-migration sheath 6ₐ is just as effective as its FIG. 1 counterpart 6 which is formed as by the sputtering, vapor deposition, or coating of an electrically insulating, inorganic substance. The anti-migration sheath 6ₐ may be formed on any desired part or whole of the side of the LED chip, as was set forth in conjunction with first described embodiment.

### Embodiment of FIG. 9

Still another preferred form of LED chip shown in FIG. 9 is similar in construction to that of FIG. 1 except for a modified anti-migration sheath 6_{b} and, newly introduced in this embodiment, a current block or current baffle 31. The anti-migration sheath 6_{b} is comprised of an inside layer 6_{b1} on the side 22 of the reflector layer 2, and an outside layer 6_{b2} covering not only the inside layer 6_{b1} but additionally the side 23 and major surface 18 of the light-generating semiconductor region 3 and part of the side 24 of the baseplate 1. The inside layer 6_{b1} is formed by ion implantation like the anti-migration sheath 6ₐ of the FIG. 8 embodiment. The outside layer 6_{b2} is formed by the sputtering, vapor deposition, or coating of an electrically insulating, inorganic substance. Metal migration from the reflector layer 2 is even more positively inhibited than in the two preceding embodiments, the side of the reflector layer being dually sheathed by the inside layer 6_{b1} and outside layer 6_{b2}.

Made from electrically insulating material, the current baffle 31 is buried centrally in the reflector layer 2 and so held against the first major surface 17 of the light-generating semiconductor region 3 in register with the anode 4. The current baffle 31 serves to reduce the current flowing through that part of the active layer 12 which lies opposite the anode 4, to relatively augment the current flowing through the outer part of the active layer, and hence to enhance the efficiency of the LED. A similar current baffle could be employed in any of the other embodiments disclosed herein.

### Embodiment of FIG. 10

A further preferred form of LED chip shown in FIG. 10 has a light-generating semiconductor region 3 that tapers upwardly, or in a direction away from the baseplate 1. Further, as seen in a plan view or from above in FIG. 10, the baseplate 1 is made larger than the light-generating semiconductor region 3 to provide an annular ledge around the same. The cathode 5 is positioned on this annular ledge of the baseplate 1, that is, on the same major surface 15 of the baseplate as is the light-generating semiconductor region 3. All the other details of construction of this LED are similar to those set forth in connection with the FIG. 1 embodiment.

The cathode 5 is shown overlying the bonding agent layer 2_{b} which is shown covering the complete major surface 15 of the baseplate 1. As has been stated in conjunction with the manufacturing method, illustrated in FIGS. 2-6, of the FIG. 1 embodiment, the bonding agent layer 2_{b} is fused under heat and pressure to the bonding agent layer 2ₐ, thereby bonding the baseplate 1 to the light-generating semiconductor region 3 and at the same time creating the reflector layer 2 by the combination of both bonding agent layers.

Despite the showing of FIG. 10, the cathode 5 will be unnecessary if the bonding agent layer 2_{b} is capable of functioning as electrode. It is also unnecessary that the bonding agent layer 2_{b} underlie the cathode 5. The bonding agent layer 2_{b} may therefore leave the annular ledge of the baseplate 1 bare and itself be enclosed in the anti-migration sheath 6 together with the other bonding agent layer 2ₐ.

Enveloping the slanting side 23 of the light-generating semiconductor region, the anti-migration sheath 6 will more effectively prevent the migration of the reflector metal. The anti-migration sheaths 6ₐ and 6_{b}, FIGS. 8 and 9, could be employed in this FIG. 10 embodiment in place of the sheath 6 similar to that of FIG. 1.

### Embodiment of FIG. 11

In a further preferred form of LED chip shown in FIG. 11, the light-generating semiconductor region 3 tapers downwardly, or in a direction from the anode 4 toward the reflector 2. Another difference concerns an anti-migration sheath 6_{c} which is made up of two layers in lamination. All the other details of construction of this LED are similar to those set forth in connection with the FIG. 1 embodiment.

The sheath 6_{c} is constituted of two layers 6_{c1} and 6_{c2} of materials that differ in refractive index. Formed on the downwardly tapering surface of the light-generating semiconductor region 3, the dual-layer sheath 6_{c} serves the additional purpose of reflecting the lateral component of the light from the active layer 12 toward the light-emitting major surface 18 of the semiconductor region.

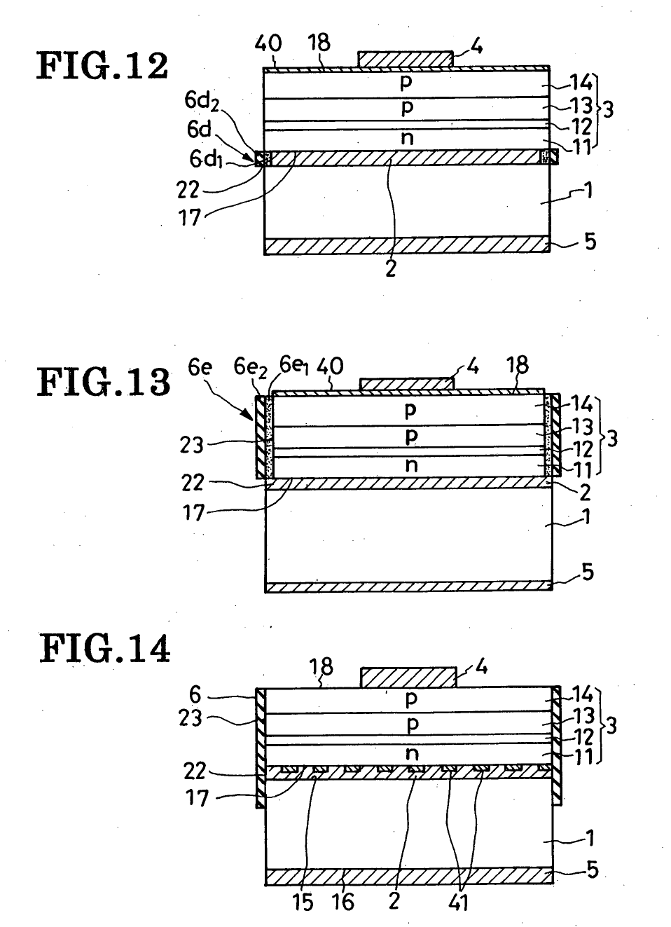

### Embodiment of FIG. 12

A dual-layer anti-migration sheath 6_{d} is formed only on the side 22 of the reflector layer 2 in a yet further preferred form of LED chip shown in FIG. 12. This LED also features a transparent electrode 40 covering the entire second major surface 18 of the light-generating semiconductor region 3. The bonding pad 4 is placed centrally on this transparent electrode 40. All the other details of construction are similar to those set forth in connection with the FIG. 1 embodiment.

The anti-migration sheath 6_{d} is a lamination of an inside layer 6_{d1} and an outside layer 6_{d2}. The inside layer 6_{d1} is formed by ion implantation into the reflector layer 2 like the sheath 6ₐ of FIG. 8. The outside layer 6_{d2} is formed by the sputtering, vapor deposition, or coating of an electrically insulating, inorganic substance on the inside layer 6_{d1} like the sheath 6 of FIG. 1.

Covering only the side 22 of the reflector layer 2, the sheath 6_{d} is nearly as effective as all its counterparts in the other embodiments disclosed herein to prevent the migration of the reflector metal onto the side 23 of the light-generating semiconductor region. The transparent electrode 40 on the entire second major surface 18 of the light-generating semiconductor region 3 is conducive to a more uniform current distribution throughout the region.

### Embodiment of FIG. 13

A further yet preferred form of LED chip shown in FIG. 13 is akin in construction to the FIG. 12 embodiment except for a dual-layer anti-migration sheath 6ₑ employed in substitution for the sheath 6_{d} of the latter. The anti-migration sheath 6ₑ is constituted of two layers 6ₑ₁ and 6ₑ₂ in lamination, which are of the same materials, and are formed by the same methods, as their counterparts 6_{d1} and 6_{d2} of the anti-migration sheath 6_{d}, FIG. 12. However, unlike the sheath 6_{d}, the anti-migration sheath 6ₑ covers the complete side 23 of the light-generating semiconductor region 3, leaving the side 22 of the reflector layer 2 bare.

The anti-migration sheath 6ₑ is just as effective as the FIG. 12 sheath 6_{d} to prevent the migration of the reflector metal onto the side of the light-generating semiconductor region 3. Additionally, the sheath 6ₑ functions to render the light-generating semiconductor region moisture-proof.

### Embodiment of FIG. 14

An open-worked ohmic contact layer 41 is inserted between reflector layer 2 and light-generating semiconductor region 3 in a still further preferred form of LED chip shown in FIG. 14. This LED chip is identical in all the other details of construction with that of FIG. 1.

It is understood that the reflector layer 2 of this embodiment is of aluminum and so itself makes rather unsatisfactory ohmic contact with the n-type cladding 11 of the light-generating semiconductor region 3. Favorable electric connection between these parts is nevertheless assured as the interposed ohmic contact layer 41 makes ohmic contact with both of them.

Incorporating the anti-migration sheath 6 of the same design as that of FIG. 1, this FIG. 14 embodiment possesses the same advantages as the first described embodiment. The ohmic contact layer 41 could be employed in any of the FIGS. 8-13 embodiments.

### Possible Modifications

Notwithstanding the foregoing detailed disclosure it is not desired that the present invention be limited by the exact showings of the drawings or the description thereof. The following is a brief list of possible modifications, alterations or adaptations of the illustrated exemplary embodiments and manufacturing method thereof according to the invention which are all believed to fall within the purview of the claims annexed hereto:

1. The anti-migration sheath could be of electrically insulating, organic substances, in which case the sheath would have to make closer contact with the light-generating semiconductor region 3 than the plastic encapsulation 10.

2. An ohmic contact layer could be provided on the entire first major surface 17 of the light-generating semiconductor region 3.

3. The light-generating semiconductor region 3 may be made from semiconductors other than nitrides, examples being aluminum gallium indium phosphide and derivatives thereof.

4. A buffer layer of aluminum indium gallium nitride or the like could be interposed between reflector layer 2 and light-generating semiconductor region 3.

5. The light-emitting surface 18 of the light-generating semiconductor region 3 could be knurled, beaded or otherwise roughened for higher efficiency of light emission.

6. The first electrode 4 could be formed on the p-type cladding 13 or in other than the illustrated position on the complementary layer 14.

7. The baseplate 1 could be metal made for combined use as electrode, in which case the second electrode 5 would be unnecessary.

8. The indicated conductivity types of the layers of the light-generating semiconductor region 3 are reversible.

9. The baseplate 1 when made from semiconductors may incorporate a diode or other semiconductor device.

10. A current baffle could be provided on the light-emitting major surface 18 of the semiconductor region 3 in combination with a transparent electrode 40, FIGS. 12 and 13.

11. The baseplate 1 could be bonded to the light-generating semiconductor region 3 with only either of the bonding agent layers 2ₐ and 2_{b}.

12. The substrate 30 for growing the light-generating semiconductor region 3 whereon could be of sapphire or other electrically insulating material.

13. The surface of the anti-migration sheath 6 could also be knurled or beaded for a greater surface area and hence for a higher efficiency of light emission.

What is claimed is:

1. A light-emitting semiconductor device protected against the migration of metal, comprising:
(a) a baseplate;
(b) a conductor layer formed on the baseplate, the conductor layer being made from a metal that is relatively easy to migrate;
(c) a light-generating semiconductor region coupled to the baseplate via the conductor layer and comprising at least two semiconductor layers of opposite conductivity types for generating light;
(d) an electrode on the light-generating semiconductor region; and
(e) an anti-migration sheath enveloping at least either of the conductor layer and the light-generating semiconductor region for preventing the metal of the conductor layer from migrating onto the light-generating semiconductor region, the anti-migration sheath being higher in electric resistivity than the conductor layer and the light-generating semiconductor region.

2. A migration-proof light-emitting semiconductor device as defined in claim 1, wherein the anti-migration sheath is made from an inorganic compound.

3. A migration-proof light-emitting semiconductor device as defined in claim 1, wherein the anti-migration sheath is made from an electrically insulating substance containing an element contained in the conductor layer.

4. A migration-proof light-emitting semiconductor device as defined in claim 1, wherein the anti-migration sheath is made from a substance which contains an element contained in the light-generating semiconductor region and which is higher in electric resistivity than the light-generating semiconductor region.

5. A migration-proof light-emitting semiconductor device as defined in claim 1, wherein the anti-migration sheath comprises a first layer held against at least either of the conductor layer and the light-generating semiconductor region, and a second layer covering at least part of the first layer.

6. A migration-proof light-emitting semiconductor device as defined in claim 5, wherein the first layer of the anti-migration sheath is made from an electrically insulating substance containing an element contained in the conductor layer.

7. A migration-proof light-emitting semiconductor device as defined in claim 5, wherein the first layer of the anti-migration sheath is made from a substance which contains an element contained in the light-generating semiconductor region and which is higher in electric resistivity than the light-generating semiconductor region.

8. A migration-proof light-emitting semiconductor device as defined in claim 5, wherein the second layer of the anti-migration sheath is made from an organic or inorganic substance.

9. A migration-proof light-emitting semiconductor device as defined in claim 1, wherein the anti-migration sheath is transparent to the light generated by the light-generating semiconductor region.

10. A migration-proof light-emitting semiconductor device as defined in claim 1, wherein the conductor layer is made from a reflective metal for reflecting the light from the light-generating semiconductor region.

11. A migration-proof light-emitting semiconductor device as defined in claim 1, wherein the conductor layer is a bonding of a first bonding agent layer on the light-generating semiconductor region and a second bonding agent layer on the baseplate.

12. A migration-proof light-emitting semiconductor device as defined in claim 1, wherein the light-generating semiconductor region tapers as the same extends away from the conductor layer.

13. A migration-proof light-emitting semiconductor device as defined in claim 1, wherein the light-generating semiconductor region tapers as the same extends toward the conductor layer, and wherein the anti-migration sheath is reflective.

14. A migration-proof light-emitting semiconductor device as defined in claim 1, wherein the light-generating semiconductor region has an active layer between the two second semiconductor layers of opposite conductivity types, and wherein the anti-migration sheath envelopes the active layer.

15. A migration-proof light-emitting semiconductor device as defined in claim 14, wherein the anti-migration sheath additionally envelopes the conductor layer.

16. A method of fabricating a light-emitting semiconductor device protected against the migration of meal, which comprises:
(a) successively growing at least two semiconductor layers of opposite conductivity types in a vapor phase on a substrate for creating a semiconductor region capable of generating light, the light-generating semiconductor region having a first major surface facing away from the substrate and a second major surface held against the substrate;
(b) bonding a baseplate to the first major surface of the light-generating semiconductor region with a bonding metal that is relatively easy to migrate, the bonding metal creating a conductor layer between the light-generating semiconductor region and the baseplate;
(c) removing the substrate from the second major surface of the light-generating semiconductor region;
(d) forming an electrode on the light-generating semiconductor region; and
(e) creating an anti-migration sheath around at least either of the conductor layer and the light-generating semiconductor region for preventing the metal of the conductor layer from migrating onto the light-generating semiconductor region, the anti-migration sheath being higher in electric resistivity than the conductor layer and the light-generating semiconductor region.

17. A method of fabricating a migration-proof light-emitting semiconductor device as defined in claim 16, wherein the anti-migration sheath is formed by a selected one of sputtering, vapor deposition, coating, and ion implantation.

18. A method of fabricating a migration-proof light-emitting semiconductor device as defined in claim 16, wherein the baseplate is bonded to the light-generating semiconductor region via a layer of the bonding metal preformed on at least either of the baseplate and the light-generating semiconductor region.

19. A method of fabricating a migration-proof light-emitting semiconductor device as defined in claim 16, wherein the baseplate is bonded to the light-generating semiconductor region by:
(a) creating a first layer of the bonding metal on the light-generating semiconductor region:
(b) creating a second layer of the bonding metal on the baseplate; and
(c) uniting the first and the second layer of the bonding metal under heat and pressure.
